(19) United States
(12) Patent Application Publication
(10) Pub. No.: US 2012/0139574 A1
(43) Pub. Date: Jun. 7, 2012

(54) VERTICAL PROBE TIP ROTATIONAL SCRUB AND METHOD

(75) Inventors: John J. Cassels, Marlboro, NY (US); Garry L. Moore, Hopewell Junction, NY (US); Ronald A. Feroli, Walden, NY (US)

(73) Assignee: International Business Machines Corporation, Amonk, NY (US)

(21) Appl. No.: 12/960,604

(22) Filed: Dec. 6, 2010

(51) Int. Cl. G01R 31/20

(52) U.S. Cl. 324/758.01

(57) ABSTRACT

A vertical probe tip rotational scrub and method is described. The vertical probe includes a wafer prober chuck; a wafer positioned on the wafer prober chuck; and at least one probe having a probe tip, the at least one probe tip rotatably mounted such that the probe tip provides a rotational scrub on a surface of a wafer surface. A method for wafer probing is also described, the method includes: determining a vertical location of a wafer surface relative to at least one probe having a probe tip; retracting the probe tip; and imparting an upward motion on the at least one probe in response to the retracting of the probe tip, wherein the upward motion results in a rotational scrub of the wafer surface.

### TECHNICAL FIELD

The present disclosure relates generally semiconductor wafer probes. In particular, the present disclosure is directed to a vertical probe tip rotational scrub and method.

### BACKGROUND

Semiconductor devices are typically formed on a semiconductor substrate employing precise photolithographic techniques. A plurality of devices is formed on a single wafer, and, upon completing the fabrication process, the wafer is sliced into separate individual deices. Prior to slicing, the semi-finished devices are typically tested on the semiconductor wafer using a wafer probe apparatus to; for example, evaluate the electrical characteristics of each device. Increasingly, however, complex integrated circuit designs and die pad geometries require wafer probe capabilities that are unattainable using current conventional probe card technologies.

Conventional probe technologies include cantilever type probes pins and vertically-aligned probe pins. Today's industry standard for wafer probing at all metal levels is the cantilever probes. Cantilever probes include a plurality of substantially horizontal cantilever probes pins extending radially inward from a probe card. Contact pressure is determined by the amount of shear strain, or bending displacement, of the probe pin tip, and the pin's spring constant. Since the spring constant, hence the contact force, decreases with increasing cantilever length, poor or incomplete penetration of a device's inner bond pad's passivation layer may result when using longer cantilever probe pins. Accordingly, cantilever-type probes are typically design restricted to devices having peripheral device bond pads. By design, cantilever probes provide a natural scrub action to break through build up oxides as the probes are driven into the wafer pads. This scrubbing action reduces contact resistance and ensures good electrical measurements. However, horizontal cantilever probes include relatively low pin densities. The number of probe pins that can physically fit within the geometry of a high-density device is limited by how closely the cantilever probe pins may be spaced. Physical limitations, such as pin diameter, pin tip spacing tolerances and the like, restrict the number of cantilever probes that may be incorporated into the cantilever probe system, thus limiting the number of bond pads which may be addressed at one time. Thus, as the demand for wafer real estate increases, pad sizes and pitch are getting smaller making the use of cantilever probes more difficult. In addition, advances in semiconductor process technology, materials and dimensions are becoming increasingly sensitive to mechanical disruptions to the planer surfaces caused by probing. Consequently, cantilever-type probes are typically restricted to testing only one device at a time. Other problems with cantilever-type probes associated with non-uniform cantilever pin lengths include difficulty in aligning the probe tips in the X-Y plane, and poor z-planarity of the probe tips. This particular problem results in imprecise probe tip placement, as well as uneven probe tip contact pressure, thus resulting in lower device yields due to bond pad damage, wire connection damage, and particulate contamination. Another problem with cantilever probe systems is the increasing probe count, or probe pin density, necessary to accommodate increasing bond pad density. Yet another problem with cantilever probe assemblies is their relative low pin densities as compared to vertical probes. These and other issues are driving the semiconductor industry to alternative probe designs.

A significantly improved new design is the vertical probe. Vertical probe pin cards include generally vertically aligned, straight pins arranged in an ordered, addressable array. The array coincides with the bond pad positions of the devices under test. Vertical probe pin densities may be higher than cantilever-type probes, and multiple devices may be tested by one probe (i.e. grid array probing). In particular, the contact force of vertical-type probe pins is determined by either the compressive strain of the pin, or by a spring, or resilient material, against which the end of the probe pin may act.

However, the vertical probe is not without problems. For example, in the vertical probe the contact force of the probe pins increases with increasing vertical displacement of the probe tip. Thus, to ensure uniform probe tips must be carefully aligned in the z-plane; i.e., a high probe tip planarity. Another problem with vertical probe pin assemblies is the criticality of precise vertical control of the probe assembly. Vertical probes contact the wafer pads orthogonally and do not have a natural scrub or wiping action during contact. This leads to higher contact resistance and poorer contact reliability over many touchdowns and process variations. Another problem with vertical pin probes arises as the bond pad density increases with increasing integration density of a semiconductor device. The resulting increase in the number of probe pins needed to test the semiconductor device exerts a correspondingly increased cumulative force on the semiconductor device and probe card.

Accordingly, it is the object of the present disclosure to provide a wafer probe system to improve contact resistance, long term data integrity reliability and reduction of process concerns through rotation of the probe tips during overdrive which will provide a wiping action via the probe rotation. In addition, it is an object of the present disclosure to provide an automated probe cleaning, which is done periodically as the wafer is tested.

### SUMMARY

The present disclosure is directed to a structure and method for rotational scrub of a wafer surface. In one embodiment a wafer probe system is described. The system includes

A wafer prober chuck; a wafer positioned on the wafer prober chuck; and at least one probe having a probe tip, the at least one probe tip rotatably mounted such that the probe tip provides a rotational scrub on a surface of a wafer surface. The probe tip of the at least one probe rotates about a vertical axis for scrubbing the surface of the wafer.

In one particular embodiment, the wafer probe system further includes a guide plate, wherein the at least one probe includes a shaft fixedly positioned on the guide plate; and a buckling beam arrangement in relationship to the guide plate for imparting a retracting motion on the at least one probe. In this particular embodiment, the retraction motion results in a rotational movement of the at least one probe. In particular, the rotational movement of the at least one probe results in the rotational scrub on a surface of the wafer. More in particular, the probe tip is rotatably connected to the guide plate. The guide plate includes a drive device for rotating the at least one probe about a vertical axis. In further embodiments, the buckling beam arrangement imparts a rotational movement on a tip portion of the at least one probe.

In another embodiment, the at least one probe includes a shaft, the shaft having a non-circular configuration. In this particular embodiment, the guide plate includes a cam action actuating the non-circular configuration of the at least one probe.

A method for wafer probing is also described. In one embodiment method includes: aligning a wafer on a chuck mechanism for determining a vertical location of a wafer surface; positioning the wafer adjacent to a probe tip; bringing the wafer into contact with the probe tip; actuating a scrub on the wafer surface; and rotating the probe tip for providing a rotational scrubbing action on the wafer surface. The step of determining the vertical location includes using optical means. In addition, the step of positioning the wafer adjacent to a probe tip includes positioning the wafer underneath the probe tip. In one embodiment, the step of actuating a lateral scrub includes providing an overdrive for ensuring contact and enacting a lateral scrub of the wafer pad surface. In another embodiment, the rotational scrub is achieved by means of a guide plate. In yet another embodiment, the step of rotating the probe tip includes imparting an upward motion such that the motion causes the probe to twist resulting in the rotational scrub.

In another embodiment, the method for wafer probing includes determining a vertical location of a wafer surface relative to at least one probe having a probe tip; retracting the probe tip; and imparting an upward motion on the at least one probe in response to the retracting of the probe tip, wherein the upward motion results in a rotational scrub of the wafer surface. In this particular embodiment the step of imparting an upward motion is initiated upon contact between the wafer surface and the probe tip. In other embodiments, a cam action imparts the rotational scrub. In yet another embodiment, the probe tip is retracted by a buckling beam arrangement.

Other features of the presently disclosed vertical probe tip rotational scrub and method will become apparent from the following detailed description taken in conjunction with the accompanying drawings, which illustrate, by way of example, the presently disclosed structure and method.

### BRIEF DESCRIPTION OF THE DRAWINGS

The features of the presently disclosed vertical probe tip rotational scrub and method will be described in detailed hereinbelow, with references to the accompanying drawings, in which:

FIG. 1 illustrates a simplified side view of a cantilever type probe tip, found in the prior art;

FIG. 2 illustrates a simplified side view of a vertical type probe tip found in the prior art;

FIG. 3 illustrates a side view of a vertical type probe having rotational scrub, in accordance with one embodiment of the present disclosure;

FIG. 4 illustrates a simplified schematic diagram of a vertical type probe having rotational scrub, in accordance with another embodiment of the present disclosure; and

FIG. 5 is an exemplary flow diagram illustrating the method of in-line wafer probing, in accordance with the present disclosure.

### DETAILED DESCRIPTION

Referring now to the drawing figures, wherein like reference numerals identify identical or corresponding elements, an embodiment of the presently disclosed vertical probe tip rotational scrub structure and method, will be described in detail. In the following description, numerous specific details are set forth, such as particular structures, components, material, dimensions and techniques, in order to provide a thorough understanding of the disclosure. However, one skilled in the art will appreciate that the invention may be practiced without these specific details. In other instances, well-known structures or processing steps have not been described in detail to avoid obscuring the invention.

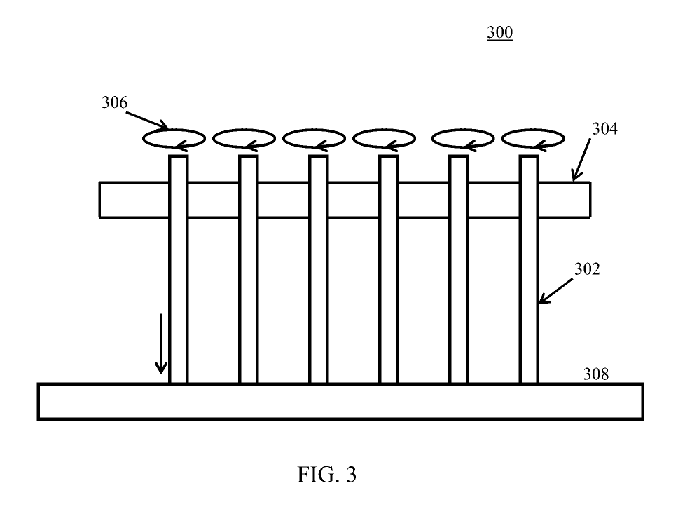

With reference to FIGS. 3-5, an improved vertical probe is described and illustrated that incorporates a mechanism that rotates a probe as it is imparted to a probe pad surface. By this small rotation, the surface oxidation is breached and good electrical contact is achieved with significantly reduced surface damage.

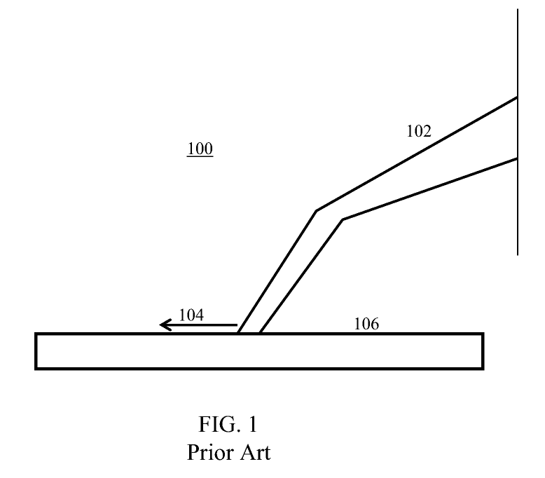

FIG. 1 illustrates a current design of a cantilever type probe tip 100. The probe tip 102 creates a lateral scrub on the surface of wafer 106. Although good electrical contact is achieved, current and future probe pad dimension and process sensitivities to this approach are forcing a vertical probe tip solution.

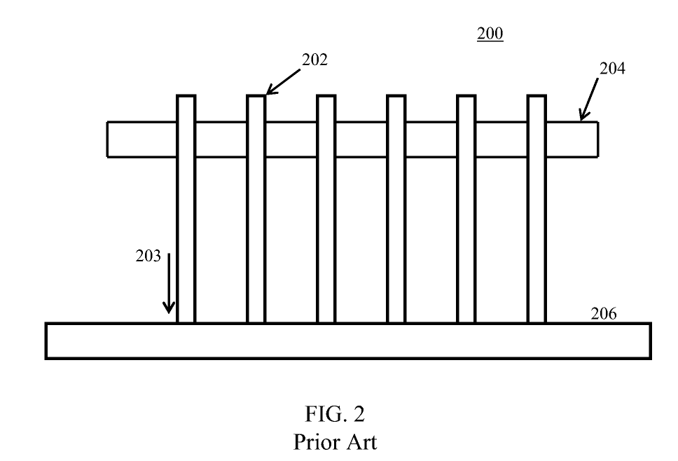

FIG. 2 illustrates a vertical type probe tip 200. Probe tip 200 includes a plurality of probes 202 positioned on an interposer 204. As illustrated by the directional arrow 203, the probe 202 does not have a natural scrub action, which occurs with overdrive and simply pressing on the pad surface does not guarantee surface oxide will be breached. That is, probe 200 does not impart a scrubbing action on the surface of wafer 206. Thus, although probe tip 200 accommodates the lateral probe pad dimension concerns, the lack of scrub results in reliable electrical contact concerns.

With reference to FIG. 3, a vertical type probe 300 having a rotational scrub, in accordance with the present disclosure is illustrated. Vertical probe 300 includes a plurality of probes 302 fixed to an interposer 304. The individual probe tip rotation 306 provides a scrub action on the surface of a wafer 308 thus ensuring good electrical contact.

With continued reference to FIG. 3, during wafer test, the wafer is placed on a chuck and aligned. After optically determining the vertical location of the wafer surface and probe tips, the wafer is brought beneath the probe tips at a precise location. The chuck is raised until initial contact is presumed. The chuck is then raised an additional amount which provides an overdrive to ensure contact and enact a rotational scrub of the wafer pad surface. An individual rotation provided to each probe tip upon contact and overdrive to the wafer surface maintains the small footprint advantages of a vertical probe design but also provides a rotational scrubbing action to breach surface oxides.

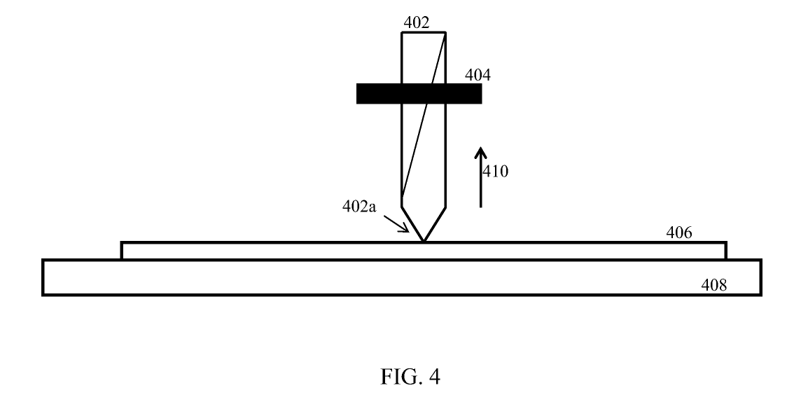

With reference to FIG. 4, the rotational scrub may be achieved by way of a non-circular probe shaft 402 fixedly attached to a guide plate 404. As probe 402 makes contact with the surface of a wafer 406, there is a retraction (directional arrow 410) of the probe tip 402a, facilitated by a commonly used buckling beam arrangement. As the probe 402 retracts, it is rotated by way of the guide plate 404. The buckling beam design allows for a controlled vertical force through compliance of the probe material.

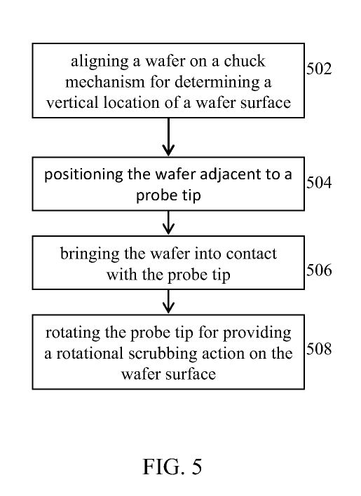

With reference to FIG. 5, in conjunction with FIGS. 3 and 4, a flow diagram of an exemplary method for wafer probing, in accordance with the present disclosure, is illustrated. In accordance with the present disclosure, initially, at step 502, a wafer 306 is aligned on a chuck mechanism (referenced by numeral 408 in FIG. 4) for determining a vertical location of a wafer surface. At step 504, the wafer is positioned adjacent to a probe tip 302. At step 506, the wafer is brought into contact with the probe tip. Finally, at step 508, a scrubbing action is actuated on the wafer by the probe tip.

It will be understood that numerous modifications and changes in form and detail may be made to the embodiments of the presently disclosed vertical probe tip rotational scrub and method. It is contemplated that numerous other method and system may be used. In particular, it is contemplated that the mechanism for rotating the probes may be selected from numerous types of mechanisms other than those specifically disclosed. Therefore, the above description should not be construed as limiting the disclosed system and method, but merely as exemplification of the various embodiments thereof. Those skilled in the art will envision numerous modifications within the scope of the present disclosure as defined by the claims appended hereto. Having thus complied with the details and particularity required by the patent laws, what is claimed and desired protected is set forth in the appended claims.

What is claimed is:

1. A wafer probe system comprising.
a wafer prober chuck;
a wafer positioned on the wafer prober chuck; and
at least one probe having a probe tip, the at least one probe tip rotatably mounted such that the probe tip provides a rotational scrub on a surface of a wafer surface.

2. The wafer probe system of claim 1, wherein the probe tip of the at least one probe rotates about a vertical axis for scrubbing the surface of the wafer.

3. The wafer probe system of claim 1, further comprising:
a guide plate, wherein the at least one probe includes a shaft fixedly positioned on the guide plate; and
a buckling beam arrangement in relationship to the guide plate for imparting a retracting motion on the at least one probe.

4. The wafer probe system of claim 3, wherein the retraction motion results in a rotational movement of the at least one probe.

5. The wafer probe system of claim 4, wherein the rotational movement of the at least one probe results in the rotational scrub on a surface of the wafer.

6. The wafer probe system of claim 3, wherein the probe tip is rotatably connected to the guide plate.

7. The wafer probe system of claim 3, wherein the guide plate includes a drive device for rotating the at least one probe about a vertical axis.

8. The wafer probe system of claim 1, wherein the at least one probe includes a shaft, the shaft having a non-circular configuration.

9. The wafer probe system of claim 3, wherein the at least one probe includes a shaft having a non-circular configuration and further wherein the guide plate includes a cam action actuating the non-circular configuration of the at least one probe.

10. The wafer probe system of claim 3, wherein the buckling beam arrangement imparts a rotational movement on a tip portion of the at least one probe.

11. A method for wafer probing, the method comprising:
aligning a wafer on a chuck mechanism for determining a vertical location of a wafer surface;
positioning the wafer adjacent to a probe tip;
bringing the wafer into contact with the probe tip;
actuating a scrub on the wafer surface; and
rotating the probe tip for providing a rotational scrubbing action on the wafer surface.

12. The method for wafer probing as recited in claim 11, wherein determining the vertical location includes using optically means.

13. The method for wafer probing as recited in claim 11, wherein the step of positioning the wafer adjacent to a probe tip includes positioning the wafer underneath the probe tip.

14. The method for wafer probing as recited in claim 11, wherein the step of actuating a lateral scrub includes providing an overdrive for ensuring contact and enacting a lateral scrub of the wafer pad surface.

15. The method for wafer probing as recited in claim 11, wherein the rotational scrub is achieved by means of a guide plate.

16. The method for wafer probing as recited in claim 11, wherein the step of rotating the probe tip includes imparting an upward motion such that the motion causes the probe to twist resulting in the rotational scrub.

17. A method for wafer probing, the method comprising:
determining a vertical location of a wafer surface relative to at least one probe having a probe tip;
retracting the probe tip; and
imparting an upward motion on the at least one probe in response to the retracting of the probe tip, wherein the upward motion results in a rotational scrub of the wafer surface.

18. The method for wafer probing as recited in claim 17, wherein the step of imparting an upward motion is initiated upon contact between the wafer surface and the probe tip.

19. The method for wafer probing as recited in claim 17, wherein a cam action imparts the rotational scrub.

20. The method for wafer probing as recited in claim 17, wherein the probe tip is retracted by a buckling beam arrangement.
